(19) United States
(12) Patent Application Publication
(10) Pub. No.: US 2007/0011556 A1
(43) Pub. Date: Jan. 11, 2007

(54) Media packet structure for real time trasnmission via packet switched networks

(76) Inventor: Philippe Gentric, Fourqueux (FR)

Correspondence Address: PHILIPS INTELLECTUAL PROPERTY & STANDARDS, P.O. BOX 3001, BRIARCLIFF MANOR, NY, 10510, US

(21) Appl. No.: 10/573,546

(22) PCT Filed: Sep. 14, 2004
(86) PCT No.: PCT/IB04/03044

§ 371 Date: Mar. 27, 2006

(30) Foreign Application Priority Data
Sep. 3, 2003 (EP) 03300137.1

(51) Int. Cl. H03M 13/00

(52) U.S. Cl. 714/752

(57) ABSTRACT

The present invention proposes a media packet structure comprising an insensitive part (ISP) comprising a block of media data (BMD) and a sensitive part (SP), said sensitive part being protected by a checksum (CS), said sensitive part comprising error correction codes (FEC) for correcting the block of media data (BMD) contained in said insensitive part (ISP). With the invention, media packets with damages in their insensitive part are not rejected, but repaired using the error correction codes (FEC).

### FIELD OF THE INVENTION

The present invention relates to a media packet structure to be transmitted via a network, a transmitter for transmitting such a media packet, a receiver for receiving such a media packet, a method of transmitting such a media packet, a method of receiving such a media packet.

The invention is particularly useful for media streaming or broadcasting over the Internet.

### BACKGROUND OF THE INVENTION

Streaming or broadcasting of multimedia content over a switched packet network like the Internet are becoming widespread. The multimedia content is encoded, packetized and transmitted as media packets via the network. Such applications may be deployed error proned network connections like wireless network connections, whose radio transmissions cause bit losses in the media packets. In addition router congestions may cause random packet losses.

Both applications involve transport network protocols like for instance the User Datagram Protocol (UDP, RFC 768) and the Real Time Protocol (RTP, RFC 1889), which reject a media packet when an error has occurred and optionally ask for retransmission of the full media packet.

An issue is that too many retransmissions are not compatible with strict delay requirements of such real-time applications.

The internet draft by Larzon et al. published by the IETF (Internet Engineering Task Force) in August 2003 describes a new transport protocol, called UDP-Lite, which is similar to UDP (RFC 768), but can also serve applications that in error-prone network environments prefer to have partially damaged payloads delivered than discarded. Using UDP-Lite, a packet is organized into a sensitive part covered by a checksum and an insensitive part not covered by any checksum. Errors in the insensitive part do not cause the packet to be discarded by the transport layer at the receiving end host. It is an advantage for codecs for voice and video, which are designed for coping better with errors in the payload than with loss of entire packets.

However this class of applications which benefit from having damaged data delivered rather than discarded by the network is not always able to recover the damaged data. In such cases, quality of the displayed decoded multimedia content drops.

### SUMMARY OF THE INVENTION

The object of the invention is to propose a solution for better repairing the damaged media data.

This is achieved by a media packet structure comprising an insensitive part comprising a block of media data and a sensitive part, said sensitive part being protected by a checksum, said sensitive part comprising error correction codes for correcting the block of media data contained in said insensitive part.

When damaged, the block of media data contained in the insensitive part of the media packet in accordance with the invention can be repaired using the error correction codes contained in the sensitive part of the data packet. Such a correction may be achieved by a router, a receiver or any network device and preceeds any processing by an error resilient decoder. Therefore, with the invention, a pre-correction step is provided and the received media bitstream received by the error resilient decoder is transmitted with less errors to the decoder. Consequently, the error resilient decoder has greater chances to successfully decode the received media data. An advantage of the media packet in accordance with the invention is thus to contribute to a quality improvement of the decoded multimedia content.

Moreover, the error correction codes, which are transported in the sensitive part of the media packet in accordance with the invention, constitute reliable data. As a matter of fact, routers or receivers check that the checksum of the sensitive part of the data packet is valid before transmitting the media packet. If not, the whole media packet is rejected. Therefore, the error correction codes received by a receiver are valid and make possible an efficient correction of the media data damages.

It should be noted that the use of such error correction codes is already known from the document Request For Comment (RFC) 2733 by J. Rosenberg and H. Schulzrinne, published by the IETF in December 1999 and entitled “An RTP Payload Format for Generic Forward Error Correction”. Such a document specifies a packet data structure for transporting forward error correction codes, which allow generic forward error correction of lost real time media data. These forward error correction codes, also called Loss Erasure Codes (LEC) are put by the sender into packets which are not sent in the same stream as the media packets. A LEC packet comprises forward error correction codes for correcting one or more media packets. At the receiver side, LEC packets and original media packets are received. If no media packets are lost, the LEC codes can be ignored. In the event of loss, the LEC packets can be combined with other media and LEC packets that have been received, resulting in recovery of missing media packets.

An advantage of the media packet in accordance with the invention is that the error correction codes are stored in the same media packet than the block of media data to be repaired. The correction procedure involved at the receiver side is therefore much simpler, because there is no need to search for the LEC packet corresponding to the damaged media packet.

For compression efficiency reasons, a LEC packet is usually associated with a plurality of media packets, for instance 10 media packets. However, it is known to the man skilled in the art that the complexity of the algorithms involved for calculating the error correction codes increases with the size of the blocks of media data to be corrected. The error correction codes stored into the media packet struture in accordance with the invention are only associated with the block of media data stored into the same media packet. Therefore, with the invention, the complexity of the algorithms involved at the transmitter, router or receiver sides is reduced.

These and other aspects of the invention will be apparent from and will be elucidated with reference to the embodiments described hereinafter.

### BRIEF DESCRIPTION OF THE DRAWINGS

The present invention will now be described in more detail, by way of example, with reference to the accompanying drawings, wherein:

FIG. 1 describes a communication system in accordance with the prior art,

FIG. 2a describes an IP/UDP/RTP network protocol stack,

FIG. 2b describes a data packet structure used by the network protocol UDP-Lite,

FIG. 3a describes the structure of an UDP-Lite header,

FIG. 3b describes a media packet structure in accordance with a first embodiment of the invention,

FIG. 4 is a functional diagram of a transmitter in accordance with a first embodiment of the invention,

FIG. 5 is a functional diagram of a receiver in accordance with a first embodiment of the invention,

FIG. 6 is a functional diagram of a router in accordance with a first embodiment of the invention,

FIG. 7 describes a media packet structure in accordance with a second embodiment of the invention,

FIG. 8 is a functional diagram of a transmitter in accordance with a third embodiment of the invention,

FIG. 9 is a functional diagram of a receiver in accordance with a third embodiment of the invention.

### DETAILED DESCRIPTION OF THE INVENTION

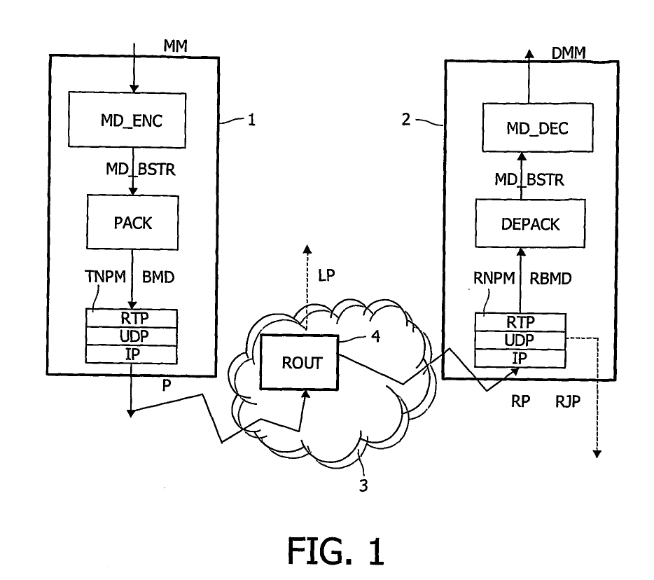

FIG. 1 is a schematic representation of a communication system in accordance with the prior art. Such a communication system comprises a transmitter 1, also called a source host, a network 2 and a receiver 3, also called a destination host. The network 2 can be any kind of packet switched network, preferably the Internet. It should be noted that the network may comprise a wireless connection, for instance from a base station to a mobile receiver, like a mobile phone.

Such a network 3 is organized as a stack of layers, each one built upon the one below. The purpose of each layer is to offer certain services to the higher layers, shielding those layers from the details of how the offered services are actually implemented. A layer on the transmitter carries a conversation with the corresponding layer on the receiver or a router in accordance with rules and conventions, which are defined by a protocol.

A classical model of network protocol stack comprises an Internet layer, which defines an official IP packet format and protocol called IP (Internet Protocol). The aim of the Internet layer is to deliver IP packets where they are supposed to go. The network protocol stack further comprises a transport layer above the Internet layer, which allow peer entities on the source and destination hosts to carry on a conversation. The transport layer is usually ruled by two end to end protocols:
the UDP protocol (User Datagram Protocol), which is an unreliable, connectionless protocol,
the RTP (Real-Time Protocol) protocol to carry data that have real time properties and possibly associated with the RTCP (Real Time Control Protocol) protocol to monitor the quality of service.

It should be noted that the transport layer may be ruled by other protocols than UDP and RTP. For instance, proprietary protocols have been developed. More generally, proprietary network protocol stack models have been implemented for dedicated applications like audio or video streaming over BlueTooth from a mobile phone to a hand-free ear piece.

It should be also noted that for other applications than Real-Time applications, RTP is replaced by the TCP (Transmission Control Protocol), a reliable connection oriented protocol, which allows a packet stream originating on the source host to be delivered without error to any destination host on the internet and which also handles control flow. The control flow provided by TCP may cause router congestions, which lead to random packet rejections at the router level.

Referring to FIG. 1, the transmitter 1 comprises an encoder MD_ENC for encoding a multimedia content MM like voice or video into a media data bitstream MD_BSTR. For video content, the encoder MD_ENC for instance implements the MPEG-4 (Moving Picture Expert Group) or the H.264 standards. For voice content, the encoder MD_ENC for instance implements the AMR (Advanced Multi Rate) standard. The media data bitstream is organized by packetizing means PACK into blocks of media data BMD, which are embedded by transmitter network protocol means TNPM into media packets MP as defined by the network protocol stack.

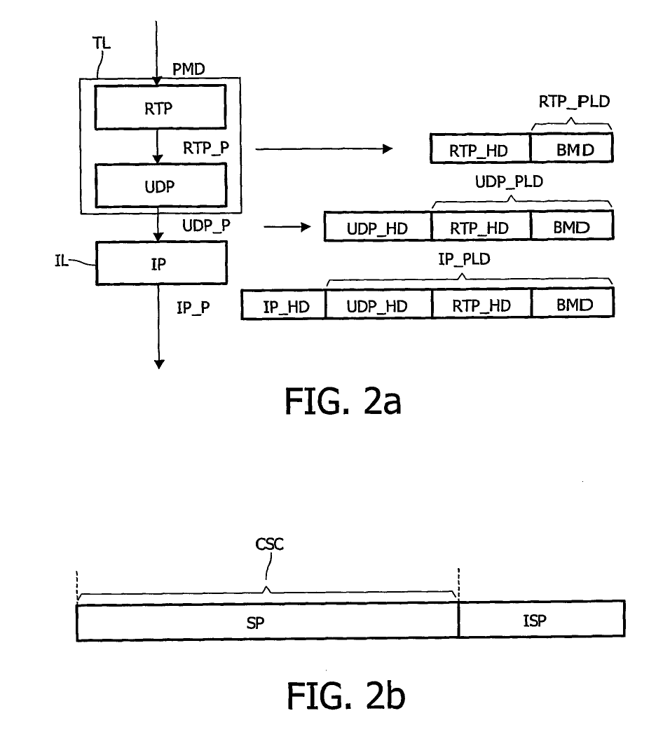

FIG. 2a describes transmitter network protocol means TNPM implementing a network protocol stack, which is adapted to real-time streaming or broadcasting applications via the Internet.

At the transmitter side, a block of media data BMD to be transmitted over the network 3 is firstly handled by the RTP protocol, which creates a RTP packet comprising a RTP header RTP_HD and a RTP payload RTP_PLD. The RTP payload is formed by the block of media data BMD and the RTP header comprises RTP related metadata, like for instance a sequence number or a time stamp for controlling the RTP payload.

The obtained RTP packet RTP_P is further handled by the UDP protocol, which creates an UDP packet UDP_P by adding an UDP header to the RTP packet. Therefore, the UDP packet comprises the UDP header followed by an UDP payload UDP_PLD. The UDP payload comprises the RTP packet and the UDP header comprises metadata like a source address, a destination address and a checksum.

The checksum is used for detecting errors in a sequence of m bits, m being an integer, to be carried by the UDP packet. A polynomial code method is advantageously employed: the transmitter and the receiver must agree upon a generator polynomial G(x) in advance. To compute the checksum of the sequence of m bits, corresponding to the polynomial M(x), the sequence of m bits must be longer than the generator polynomial G(x). The idea is to append a checksum to the end of the sequence of m bits in such a way that the polynomial represented by the sequence of m bits followed by the checksum is divisible by G(x). When the receiver gets the packet comprising the sequence of m bits and the checksum, it tries dividing it by G(x). If there is a remainder, there has been a transmission error. In this case, the UDP packet is fully rejected by the UDP protocol.

The network 2 may comprise some routers ROUT in order to route the packets P towards a specified destination.

Received packets RP are received by the receiver 3, which comprises receiver network protocol means RNPM for extracting received blocks of media data as defined by the network protocol stack. It should be noted that the receiver network protocol means RNPM are symmetrical to the transmitter network protocol means NTPM described by FIG. 2a. When an error in the checksum is detected by the UDP layer in a received packet RJP, the received packet RJP is rejected.

The received blocks of media data RBMD coming from valid packets are then depacketized by depacketizing means DEPACK, which deliver a received media data stream MD_BSTR to a decoder MD_DEC.

In the following we consider a new protocol, which allows calculating a partial checksum, that is a checksum which only covers a part of the packet. Such a protocol is for instance the UDP-Lite protocol or the DCCP (Data Congestion Control Protocol) protocol, which are not yet standardised.

FIG. 2b describes an UDP-Lite packet comprising a sensitive part SP and an insensitive part ISP, such that the checksum CS is only calculated on the sensitive part. The UDP Lite protocol only checks that the sensitive part of the packet is valid. Therefore an UDP packet comprising errors in its insensitive part may be transmitted to the RTP protocol.

Unlike the UDP protocol, the UDP-Lite protocol makes possible correcting a damaged packet instead of rejecting it. An advantage is to avoid systematic retransmission of damaged packets.

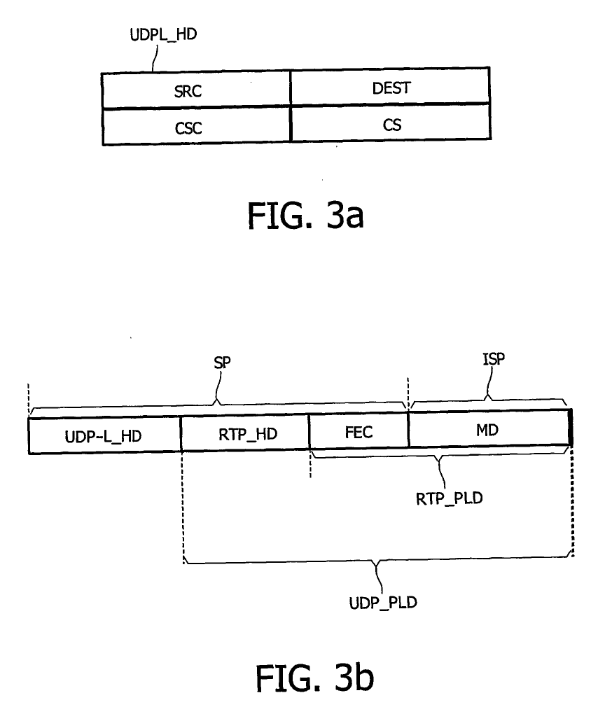

FIG. 3a describes the structure of an UDP-Lite header, which comprises, in addition to a source address SRC, a destination address DEST and a checksum value CS fields already used by the UDP protocol, a checksum coverage field CSC, which indicates a length of the sensitive part SP.

It should be noted that the sensitive part of an UDP-Lite packet is classically put at the beginning of the UDP-Lite packet, but that another protocol allowing the use of partial checksum could propose another packet structure, for instance with the sensitive part SP located at the end of the media packet.

FIG. 3b describes a media packet in accordance with the first embodiment of the invention. Such a media packet comprises a sensitive part SP and an insensitive part ISP. The insensitive part comprises the block of media data BMD to be transported by the media packet. The sensitive part SP comprises headers (RTP_HD, UDP-L_HD) added to the block of media data BMD by the RTP and the UDP-Lite protocols and error correction codes. Said error correction codes are intended to be used for correcting potential damages of the insensitive part of the data packet in accordance with the invention.

It should be noted that the invention is not limited to the UDP-Lite protocol, but to any network protocol adapted to real-time transmission of media packets and allowing the use of a partial checksum.

In the first embodiment of the invention, such error correction codes are Forward Error Correction Codes, also called FEC codes. As mentioned in the document Request For Comment (RFC) 2733 by J. Rosenberg and H. Schulzrinne, published by the IETF in December 1999 and entitled “An RTP Payload Format for Generic Forward Error Correction”, the FEC codes are traditional error correction codes, like parity, Reed-Solomon or Hamming codes. An advantage of such FEC codes is that the calculation algorithms involved to calculate such FEC codes can be reduced to XOR operations.

It should be noted that the length of the forward error correction codes inserted into the sensitive part SP of the media packet in accordance with the invention, which represents a cost of the FEC codes, is highly dependent of the requirements of the application. More FEC codes are needed for a complete correction than for a partial correction of damages in the block of media data. A trade-off needs to be made between cost and efficiency. For instance, some applications of voice transmission over IP use key word adaptive FEC codes. Such key word adaptive FEC codes are calculated and sent only when the transmission conditions get deteriorated.

The FEC codes are placed within the sensitive part SP of the media packet structure in accordance with the invention, in order to make sure that only valid FEC codes will be received by the receiver and used to correct damages in a received block of media data RBMD.

In FIG. 3b, the FEC codes are placed between the RTP header and the block of media data. An alternative position would be between the UDP header and the RTP header. More generally, it should be noted that the FEC codes may be located at any place of the sensitive part of the data packet in accordance with the invention.

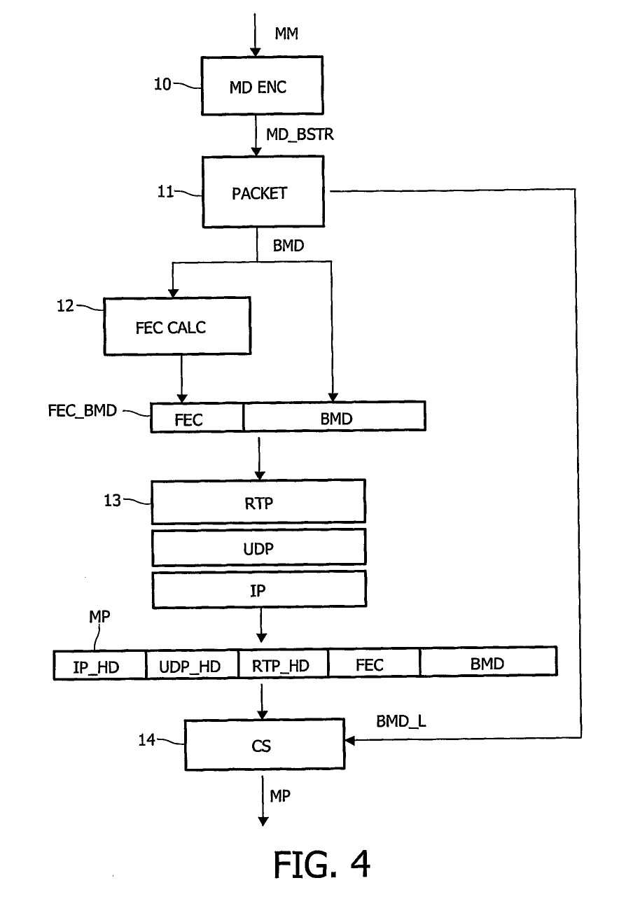

FIG. 4 describes in a functional way a transmitter for transmitting a data packet in accordance with a first embodiment of the invention. Said transmitter comprises a packetizer 10 for organizing a media bitstream MD_BDTR into blocks of media data BMD, each block being intended to be put in a media packet. A block of media data BMD is further processed by FEC calculation means 11, which are intended to calculate FEC codes for correcting either one part of or the entire block of media data BMD. It should be noted that the algorithm involved for calculating FEC codes adapted to the correction of a damaged block of media data may not be the same as the one involved for calculating FEC codes adapted to the recovery of one media data packet among a plurality of received media data packets, as described in the above mentioned document. However, such algorithms are known to the man skilled in the art.

The obtained FEC codes are further added to the block of media data BMD, in order to form a new block of data FEC_BMD. The block of data FEC_BMD is processed by the transmitter network protocol means 12, which calculate the headers related to the network protocols involved in the network protocol stack.

A media packet MP is output, in which the RTP payload comprises the block of data FEC_BMD. Checksum calculation means 14 then calculate a checksum to be written in the UDP-Lite checksum field from the knowledge of a length of the sensitive part. The length of the sensitive part is obtained by subtracting a length of the block of media data BMD_L provided by the packetizer 10 to the whole length of the media packet MP. The sensitive part SP therefore comprises the headers and the FEC codes. The length of the sensitive part BMD_L is stored into the UDP-Lite header as a checksum coverage value CSC. The checksum value corresponding to the sensitive part SP of the media packet is calculated and the checksum field CS of the UDP header of the media data packet MP is updated.

The first embodiment of the invention also relates to a method of transmitting multimedia content MM via the network 3, said method comprising the steps of:
encoding 10 said multimedia content MM into a media bitstream MD_BSTR,
packetizing 11 said media bitstream MD_BSTR into blocks of media data,
calculating 12 error correction codes FEC for a block of media data BMD,
embedding 13 said block of media data BMD into an insensitive part ISP and said error correction codes FEC into a sensitive part SP of a media packet MP,
calculating 14 a checksum CS for protecting said sensitive part SP of said media packet MP.

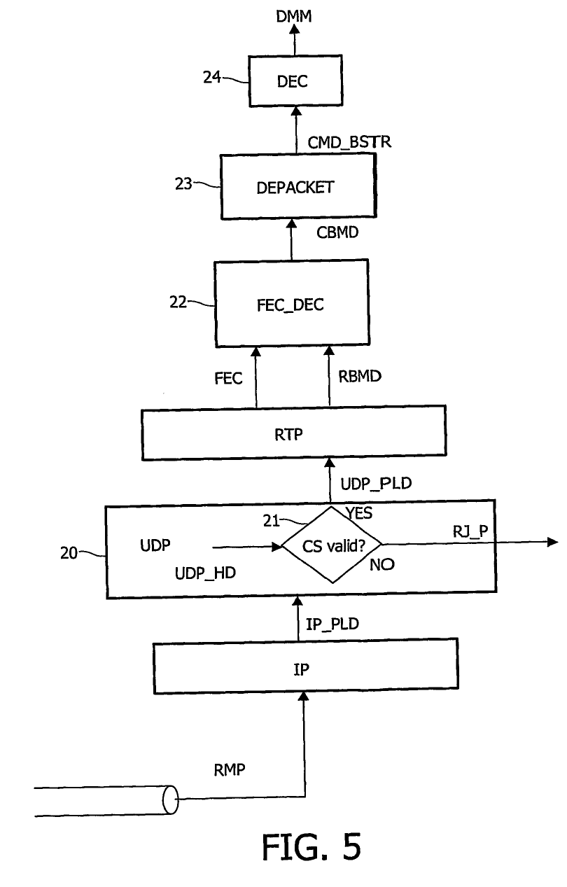

FIG. 5 describes in a functional way a receiver in accordance with the first embodiment of the invention. Such a receiver comprises receiver network protocol means 20 for applying the network protocols to a received media data packet RP. The Internet protocol IP extracts and analyses the IP header IP_HD and transmits the IP payload to the UDP-Lite protocol. The UDP-Lite protocol extracts and analyses the UDP-Lite header. In particular, checksum means 21 check the checksum CS on the sensitive part of the received packet delimited by the checksum coverage value. If the checksum CS of the received packet is valid, the UDP-Lite payload of the received packet is transmitted to the RTP layer. If not, the received packet is rejected. Then, the RTP protocol extracts and analyses the RTP header and transmits the RTP payload comprising FEC codes and a received block of media data RBMD to FEC decoding means 22. The FEC decoding means 22 are able to recalculate the block of media data from which the FEC codes were calculated. If the received block of media data RBMD is valid, the FEC codes are ignored. In the contrary, the received block of media data RBMD is corrected and a corrected block of media data CBMD is sent to the depacketizing means 23 for forming a corrected media bitstream CMD_BSTR The corrected media bitstream is further decoded by a decoder 24 so as to provide decoded multimedia content DMM.

The first embodiment of the invention also relates to a method of receiving a media packet RMP via the network 3, said method comprising the steps of:
extracting a received block of media data from an insensitive part ISP and error correction codes FEC from a sensitive part SP of said received media packet RMP,
checking whether a checksum CS protecting saif sensitive part SP is valid,
rejecting the received media packet RMP if said checksum is invalid,
correcting said received block of media data RBMD using said error correction codes FEC,
inserting said corrected block of media data CBMD to a received media bitstream RMD_BSTR,
decoding said received media bitstream RMD_BSTR.

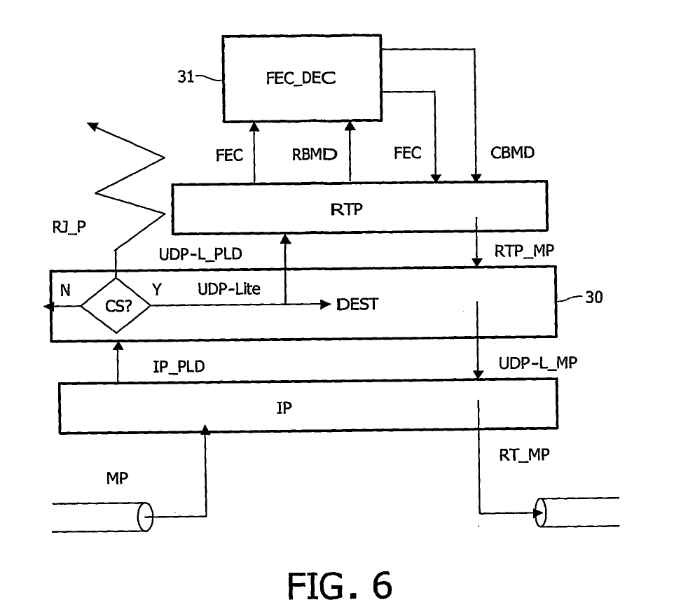

FIG. 6 describes in a functional way a router in accordance with a first embodiment of the invention. A router is intended to route the media packet MP in the right direction. To this end, the router comprises router network protocol means 30 for extracting and analyzing the headers of the network protocols up to the UDP-Lite protocol. In particular, a goal of the router network protocol means 30 is to extract the destination address of the media packet MP, which is provided by the transport layer and in our case stored into the UDP-Lite header. The UDP-Lite protocol checks the checksum CS stored into the UDP-Lite header and rejects the media packets MP having invalid checksums. Valid media packets are re-embedded and resent to the network towards their destination.

The first embodiment of the invention also relates to a method of routing a media packet RMP received via the network 3 to a receiver, said method comprising the steps of:
extracting a received block of media data RBMD from an insensitive part ISP and error correction codes FEC from a sensitive part SP of said received media packet RMP,
checking whether a checksum protecting said sensitive part SP is valid,
rejecting the received media packet if said checksum CS is invalid,
correcting the received block of media data RBMD using said error correction codes FEC,
re-embedding the corrected block of media data CBMD in an insensitive part and the error correction codes FEC in a sensitive part of a retransmitted media packet RT_MP, said sensitive part being protected by a checksum.

In the first embodiment of the invention, a block of media data BMD provided by the packetizer 10 was fully stored into the insensitive part of the media packet.

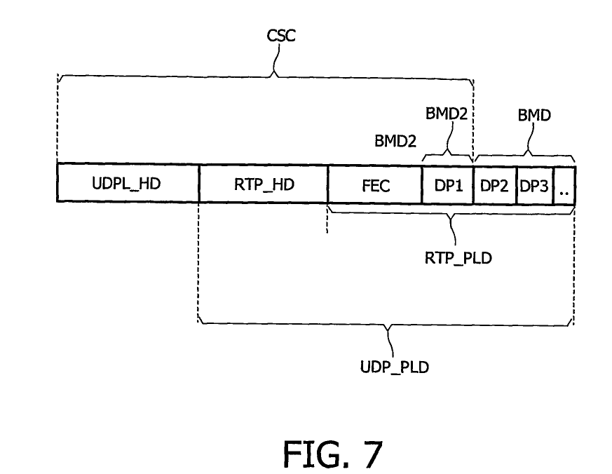

FIG. 7 describes a media packet structure in accordance with a second embodiment of the invention. In the second embodiment of the invention, the sensitive part SP of the media packet further comprises a second block of media data BMD2. The second block of media data BMD2 is therefore protected by the UDP(-Lite) checksum.

The second block of media data in accordance with the second embodiment of the invention is particularly advantageous for transporting media data, which are more important than the others, like an image size or a frame rate for a video decoder or any decoder context information. Without this kind of information, the video decoder cannot work properly. It should be noted that there are video decoders which achieve a partitioning of the media data so as to send the most important media data at the beginning of a scalable media bitstream. The second media data could for instance comprise the first data partition DP1 provided by such a video encoder and the insensitive part of the media packet the subsequent data partitions DP2, DP3 . . . DPN, N being an integer.

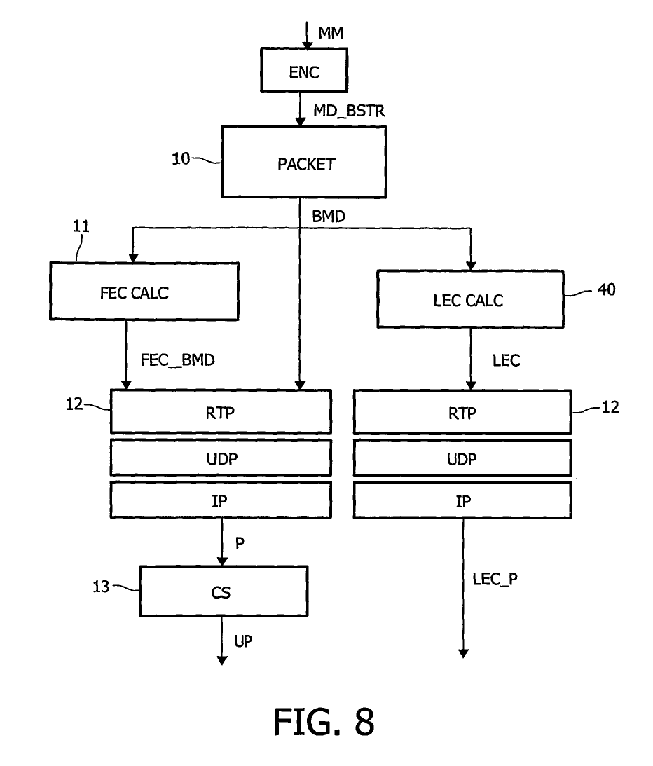

FIG. 8 describes in a functional way a transmitter in accordance with a third embodiment of the invention. Such a transmitter further comprises means 40 for calculating Loss Erasure Codes (LEC) related to the block of media data BMD which is stored into the insensitive part ISP of the media packet MP in accordance with the invention. The LEC codes are put into a packet LEC_P by the transmitter network protocol means 12 and sent over the network in another packet stream than the media packet MP comprising the corresponding block of media data. In an alternative solution, the LEC packet is sent to another port of the receiver.

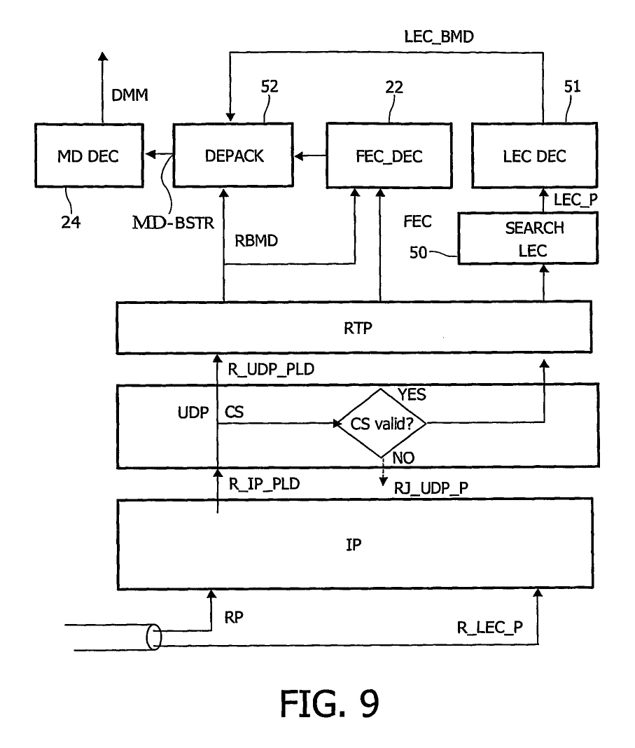

FIG. 9 describes in a functional way a receiver in accordance with the third embodiment of the invention. Such a receiver is intended to receive media data packets RP and in addition LEC packets R_LEC_P. The received media data packet RP is processed, as already described above by the receiver network protocol means 20.

If the UDP-Lite checksum CS is valid, the received media packet RP is processed as previously described.

If the UDP-Lite checksum CS is not valid, the media data packet is fully rejected. The loss of this media data packet is further noticed by the RTP protocol, which requests searching means 50 to search for the LEC packet LEC_P corresponding to the lost media packet among the received LEC packets. When found the corresponding received LEP packet LEC_P is decoded by LEC decoding means 51. A recovered block of media data LEC_BMD is sent to depacketizing means 23, which provides a recovered media bitstream LEC_MD_BSTR to the decoder 24.

As mentioned above, LEC codes are usually calculated for a plurality of blocks of media data. For instance, one LEC packet is sent for N media packets, N being an integer, approximately equal to 10. The LEC packet allows correcting one media data packet among the N media data packets. Therefore, LEC codes compensate for a loss of one media packet. If more than one media data packet is lost, complete recovery of the lost media data is not possible. However it should be noted that there are some types of LEC codes which allow partial recovery of more than one media data packet among N media data packets. This is a trade-off between error correction and compression efficiency, which depends or the requirements of the application.

Therefore, the N-1 other media packets involved in the calculation of the LEC codes are also needed in order to recover the lost media data packet.

An advantage of the third embodiment of the invention is to provide a solution for both correcting media data packets which have been received with damages and recovering completely lost packets.

The drawings and their description hereinbefore illustrate rather than limit the invention. It will be evident that there are numerous alternatives, which fall within the scope of the appended claims. In this respect the following closing remarks are made: there are numerous ways of implementing functions by means of items of hardware or software, or both. In this respect, the drawings are very diagrammatic, each representing only one possible embodiment of the invention. Thus, although a drawing shows different functions as different blocks, this by no means excludes that a single item of hardware or software carries out several functions, nor does it exclude that a single function is carried out by an assembly of items of hardware or software, or both. For instance, unlike it is described in FIGS. 1, 5 and 9, the decoder 24 could as well be a remote device, independent of the receiver 2.

Any reference sign in a claim should not be construed as limiting the claim. Use of the verb “to comprise” and its conjugations does not exclude the presence of elements or steps other than those stated in a claim. Use of the article “a” or “an” preceding an element or step does not exclude the presence of a plurality of such elements or steps.

1. A media packet structure (MP) comprising an insensitive part (ISP) comprising a block of media data (BMD) and a sensitive part (SP), said sensitive part being protected by a checksum (CS), said sensitive part comprising error correction codes (FEC) for correcting the block of media data (BMD) contained in said insensitive part (ISP).

2. A media packet (MP) as claimed in claim 1, wherein said error correction codes are forward error correction codes (FEC).

3. A media packet as claimed in claim 1, wherein comprising a second block of media data (BMP2), said second block of media data being contained in the sensitive part (SP).

4. A transmitter for transmitting multimedia content (MM) to a receiver via a network (3), said transmitter comprising:
media encoding means (10) for encoding said multimedia content (MM) into a media data bitstream (MD_BSTR),
packetizing means (11) for organizing said media data bitstream (MD_BSTR) into blocks of media data,
means (12) for calculating error correction codes (FEC) for correcting a block of media data (BMD),
transmitter network protocol means (13) for embedding said block of media data (BMD) into an insensitive part (ISP) and said error correction codes (FEC) into a sensitive part (SP) of a media-packet (MP), said transmitter network protocol means (13) comprising checksum sub-means (14) for calculating a checksum (CS) for protecting said sensitive part (SP).

5. A receiver for receiving a media packet (RMP) transmitted via a network (3), said receiver comprising:
receiver network protocol means (20) for extracting a received block of media data (RBMD) from an insensitive part (ISP) and error correction codes (FEC) from a sensitive part (SP) of said received media packet (RMP), said receiver network protocol means comprising checksum calculating sub-means (21) for checking whether a checksum (CS) calculated on said sensitive part (SP) is valid,
means (22) for correcting said received block of media data (RBMD) using said error correction codes (FEC),
depacketizing means (23) for inserting said corrected block of media data (CBMD) to a received media bitstream (RMD_BSTR),
media decoding means (24) for decoding said received media bitstream (RMD_BSTR).

6. A router for routing a media packet (MP) received via a network (3) to a receiver, said media packet comprising an insensitive part (ISP) comprising said block of media data (BMD) and a sensitive part (SP), said sensitive part being protected by a checksum (CS), said sensitive part comprising said error correction codes (FEC), said router comprising router network protocol means (30) comprising checking means for checking that said checksum is valid, and error correction means (31) for correcting said block of media data (BMD).

7. A method of transmitting multimedia content (MM) via a network (3), said method comprising the steps of:
encoding (10) said multimedia content (MM) into a media bitstream (MD_BSTR),
packetizing (11) said media bitstream (MD_BSTR) into blocks of media data,
calculating (12) error correction codes (FEC) for a block of media data (BMD),
embedding (13) said block of media data (BMD) into an insensitive part (ISP) and said error correction codes (FEC) into a sensitive part (SP) of a media packet (MP),
calculating (14) a checksum (CS) for protecting said sensitive part (SP) of said media packet (MP).

8. A method of receiving a media packet (RMP) via a network (3), said method comprising the steps of:
extracting a received block of media data from an insensitive part (ISP) and error correction codes (FEC) from a sensitive part (SP) of said received media packet (RMP),
checking whether a checksum (CS) protecting said sensitive part (SP) is still valid,
rejecting the received media packet (RMP) if said checksum is invalid,
correcting said received block of media data (RBMD) using said error correction codes (FEC),
inserting said corrected block of media data (CBMD) to a received media bitstream (RMD_BSTR),
decoding said received media bitstream (RMD_BSTR).

9. A method of routing a media packet received via a network (3) to a receiver, said method comprising the steps of:
extracting a received block of media data (RBMD) from an insensitive part (ISP) and error correction codes (FEC) from a sensitive part (SP) of said received media packet (RMP),
checking whether a checksum protecting said sensitive part (SP) is valid,
rejecting the received media packet if said checksum (CS) is invalid,
correcting the received block of media data (RBMD) using said error correction codes (FEC),
re-embedding the corrected block of media data (CBMD) in a insensitive part (ISP) and the error correction codes (FEC) in a sensitive part (SP) of a retransmitted media packet (RT_MP), said sensitive part being protected by a checksum.

10. A computer program comprising a set of instructions which, when loaded into a processor or a computer, causes the processor or the computer to carry out one of the methods as claimed in claim 7.

11. A signal carrying a computer program as claimed in claim 10.
